(19) United States
(12) Patent Application Publication
(10) Pub. No.: US 2006/0279350 A1
(43) Pub. Date: Dec. 14, 2006

(54) System and method for power management with scalable channel voltage regulation

(76) Inventors: Xin Zhang, Santa Clara, CA (US); Qin Huang, Cary, NC (US)

Correspondence Address: BLANK ROME LLP, 600 NEW HAMPSHIRE AVENUE, N.W., WASHINGTON, DC, 20037, US

(21) Appl. No.: 11/431,103

(22) Filed: May 10, 2006

Related U.S. Application Data
(60) Provisional application No. 60/679,405, filed on May 10, 2005.

(51) Int. Cl. H03K 17/00

(52) U.S. Cl. 327/407

(57) ABSTRACT

An integrated circuit power device includes a monolithic voltage regulator channel for providing low voltage high current output. The devices can be installed in parallel without a master control IC and without limitations on the number of channels to support CPU power, or can be used alone to support regular Point of Load. Novel and effective control scheme and analog circuits are provided to implement the device, including a distributed current sharing and adaptive voltage position scheme, an automatic interleaving scheme with self-adjusted carrier generator, and a novel current sensing scheme with an accurate transconductance amplifier.

### REFERENCE TO RELATED APPLICATION

This application claims the benefit of U.S. Provisional Patent Application Ser. No. 60/679,405 filed May 11, 2005, which is incorporated herein by reference in its entirety.

### FIELD OF THE INVENTION

The present invention relates generally to the field of electronic circuits, and more particularly, to electronic circuits used for power management. In exemplary embodiments, the invention can be applied to power management in high current, low voltage applications such as microprocessor power management.

### BACKGROUND OF THE INVENTION

According to industry projections, future mainstream microprocessors will require a lower voltage (0.8V vs. today's 1.5V), but will draw a higher current (150 A vs. today's 50 A), and have a tighter voltage regulation window. However, it is difficult to further increase the size of the CPU power supply. Moreover, for future CPU power management, CPU current ratings are likely to vary from 40 A to 300 A for different kinds of computers, and the number of voltage regulator (VR) channels may vary from 2 to 20.

FIG. 1 is a simplified diagram of a conventional centralized control architecture for multiphase Voltage Regulators. To achieve interleaving, a centralized interleaving block produces phase shifted clock pulse signals and sawtooth signals according to the pre-decided VR phase number. To achieve current sharing, each channel's inductor current is fed back to a dedicated current sharing block (CS). The CS block produces error signals for each channel's PWM modulator by adjusting the voltage loop error signal according to each channel's current information. The CS block can also be based on other current sharing mechanisms. To achieve Adaptive Voltage Position (AVP), the total current information and output voltage are fed back to the compensator, and the AVP performance is controlled by compensator design. Typically, the control circuits in FIG. 1 are integrated into a monolithic controller IC, and the driver for each channel's power devices is integrated as a separate driver IC. The power devices are typically discrete trench MOSFETs.

The inventors have determined that the conventional approach exemplified by the circuit shown in FIG. 1 has at least two limitations relative to future microprocessor power management: (1) power density is limited by the discrete approach in this circuit; and (2) the nature of the circuit makes flexible phase design difficult.

Lateral power MOSFET technology has been used in an effort to achieve high power density, high frequency and monolithic integration. An integrated power IC may include a voltage regulator (a multi-phase step down DC-to-DC converter of a type commonly referred to as a “buck” converter with each phase generating 15˜25 A), single channel devices and a driver. For example, Volterra Semiconductor Corporation of Fremont, Calif. offers a 15 A power IC (VT1102) that integrates one channel device and driver together and is advertised to work beyond 1 MHz with 85% efficiency. (See FIG. 2) Because of the high frequency, a small inductor can be used, and ceramic capacitors can be used on the motherboard. High frequency and integration dramatically improve power density in this device. However, the centralized control architecture in this design is an obstacle to applications that involve flexible phase design.

There have been efforts to achieve a flexible phase design in power circuits. International Rectifier of El Segundo, Calif. sells an IC product under the trademark Xphase™. When the devices sold by International Rectifier are used together and configured as shown in FIG. 3, they can handle up to 16 different phases. In this control approach, the block to achieve interleaving is distributed into N local control units and 1 main control unit. The block to achieve current sharing is distributed into N local control units. The block to achieve AVP, the compensator, is kept in the main control unit. In this way, each channel's current information is only fed back to the local control unit associated with this channel. Each channel's driver receives PWM signals from the associated local control unit. Therefore, long current feedback lines and PWM signal lines are avoided. The main control gets information only from bus lines and sends information only to the bus lines. Phases are added or removed by adding or removing a local control unit without changing the fundamental design.

However, the inventors have found that this solution is also not ideal. The International Rectifier product uses a master-slave architecture; although there is a control unit in each channel's local controller, a master controller is required. Also, a substantial number of small resisters and capacitors are needed. Leaving out the current sensing elements and the decoupling capacitors, there are still many components required for each channel, and these components cannot be integrated because of the need for accuracy in the values of these resistors and capacitors, and because changes in the number of channels requires changes in the component values. A large number of analog bus lines and connections lead to a complex layout.

Through their research, the inventors have found that conventional approaches all require a tradeoff between high power density and flexible design. Therefore, the inventors have identified a need for a new power management approach that simultaneously permits higher power density and flexible phase design.

### SUMMARY OF THE INVENTION

It is to be understood that both the following summary and the detailed description are exemplary and explanatory and are intended to provide further explanation of the invention as claimed. Neither the summary nor the description that follows is intended to define or limit the scope of the invention to the particular features mentioned in the summary or in the description.

In disclosed embodiments, a MVRC (Monolithic/Modularized Voltage Regulator Channel) design permits both flexible phase design and high power density. The term MVRC may refer to a “Monolithic Voltage Regulator Channel”, embodied in a single die step down DC-to-DC or “buck” chip. In this single die chip, one channel's power devices, drivers and control circuitry are monolithically integrated based on lateral power device technology. MVRC may also be used to refer to a “Modularized Voltage Regulator Channel”, embodied in a multi-die chip. In this multi-die chip, the top power switch can be built in a silicon die based on UMOS or DMOS technology. The bottom power switch can be built in another silicon die based on UMOS or DMOS technology. The driver and control circuitry can be integrated in another die based on CMOS or BiCMOS technology. In both of these embodiments, the MVRC is a generic power IC with power MOSFETs, drivers, and control circuitry of one channel converter integrated at the chip level. Multiple MVRC chips can be paralleled without a master control IC and without channel number limitations to support a CPU load, and a single MVRC chip may be used alone to support regular Point of Load requirements.

In an embodiment, three basic functions are included in the devices implementing MVRC chips. They are: Current Sharing among each channel, Adaptive Voltage Position and Interleaving.

In some embodiments, a fully distributed control scheme is provided to facilitate automatic current sharing and AVP (Adaptive Voltage Position) without introducing channel number limitations. Active droop control may be provided for each channel, and in some embodiments the only bus line is a DC voltage reference for each channel. Both theoretical analysis and simulations demonstrate that a combination of these approaches will meet developing CPU power requirements.

In an embodiment, a novel distributed interleaving scheme achieves automatic interleaving without channel number limitation. This scheme achieves scalable phase interleaving without changing many components. In an exemplary embodiment, a self-adjusting saw-tooth generator produces accurate phase delay and a matched saw-tooth waveform without layout matching and trimming. Each channel's circuitries for interleaving may be monolithic integrated, if desired, without any external components. The proposed interleaving scheme has broad application and can be applied, for example, to any cellular converter system.

Additional embodiments provide detailed I/O and connection methods for implementing a single integrated circuit implementation of the device, current sharing, AVP and interleaving schemes. The disclosed chip is a practical power IC both for CPU and POL loads, and can be easily standardized.

In some embodiments, a novel current sensing scheme, referred to herein as transconductance sensing, permits inductor current sensing with a small ESR in high frequency applications. Disclosed embodiments include an accurate transconductance amplifier with an analog topology that makes it possible to produce the accurate Gm without additional trimming. In embodiments where the transconductance amplifier is integrated in the MVRC chip, the customer can configure it according to the disclosure herein, or to provide inductor current sensing and resister current sensing. When AVP is needed as in often the case in CPU power management, the output voltage signal can be added to the sensed inductor current signal without an adder.

Additional features and advantages of the invention will be set forth in the description which follows, and in part will be apparent from the description, or may be learned by practice of the invention. The advantages of the invention will be realized and attained by the structure particularly pointed out in the written description and claims hereof as well as the appended drawings.

### BRIEF DESCRIPTION OF THE DRAWINGS

The accompanying drawings, which are incorporated herein and form a part of the specification, illustrate various exemplary embodiments of the present invention and, together with the description, further serve to explain various principles and to enable a person skilled in the pertinent art to make and use the invention.

FIG. 1 is a block schematic diagram of a conventional Voltage Regulator circuit;

FIG. 2 is a block schematic diagram of a conventional power circuit;

FIG. 3 is a block schematic diagram of another conventional power circuit;

FIG. 4 is a block schematic diagram showing an exemplary embodiment of a distributed control circuit;

FIG. 5 is a block schematic diagram showing an exemplary embodiment of a monolithic voltage regulator channel architecture incorporating distributed control circuits;

FIG. 6A is a schematic diagram of an exemplary embodiment of an automatic current sharing and AVP circuit;

FIG. 6B is a partial equivalent circuit diagram of the circuit of FIG. 6A;

FIG. 7 illustrates an embodiment of an interleaving circuit including a self-adjusted carrier generator;

FIGS. 8A and 8B illustrate the relationship between clock waveforms generated by the circuit of FIG. 7;

FIG. 9A is a block schematic diagram showing a portion of the interleaving circuit of FIG. 7;

FIG. 9B is a waveform diagram showing the output of the circuit of FIG. 9A;

FIG. 10 is a block schematic diagram showing an embodiment of a self-adjusted saw-tooth generator;

FIG. 11 is a detail of the reset and sample pulses of the circuit of FIG. 10;

FIG. 12 is a simulated waveform diagram showing the output of the circuit of FIG. 10;

FIG. 13 is a schematic diagram showing an embodiment of a transconductance amplifier used to convert a voltage to a current;

FIGS. 14A, 14B and 14C are exemplary schematic diagrams of inductor current sensing, resistor current sensing, and a flexible sensing circuit, respectively, all of which may use the amplifier of FIG. 13; and

FIG. 15 is a block schematic diagram of an exemplary embodiment of a circuit using the integrated devices disclosed herein for CPU power management.

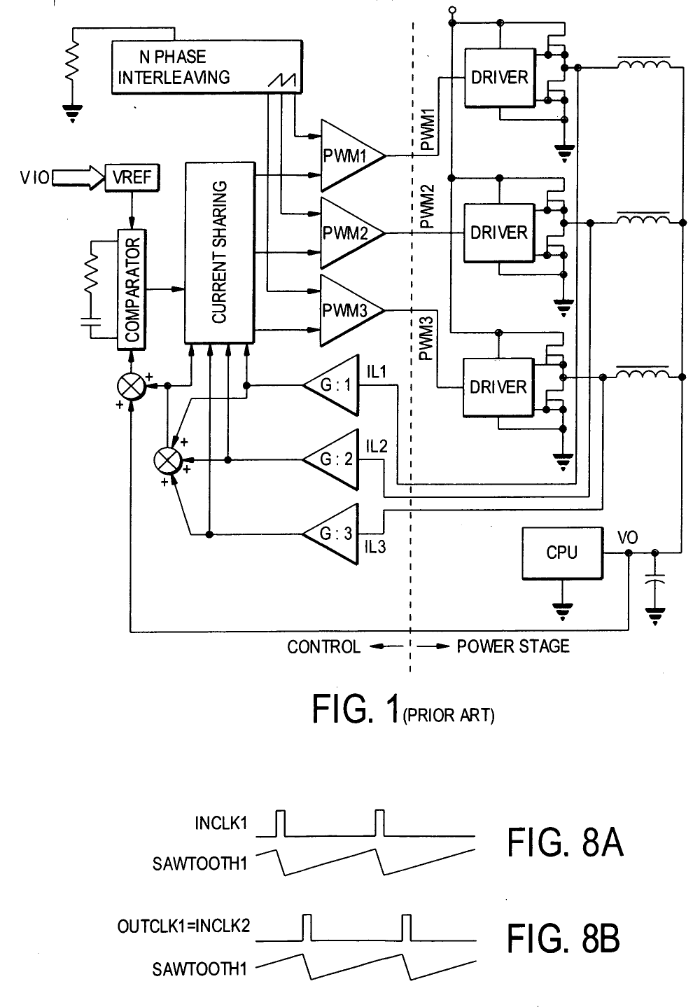

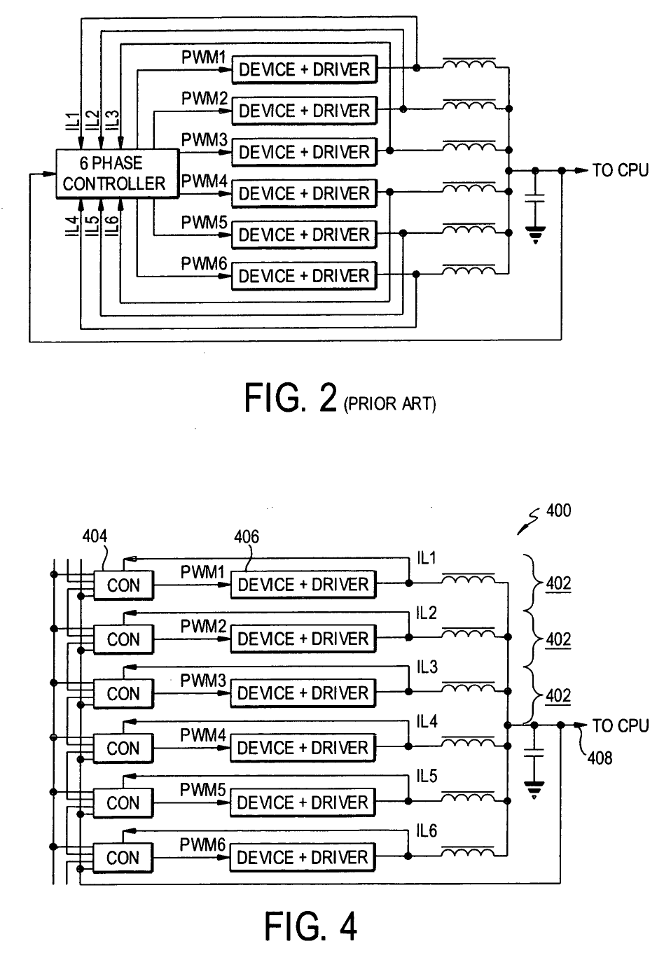

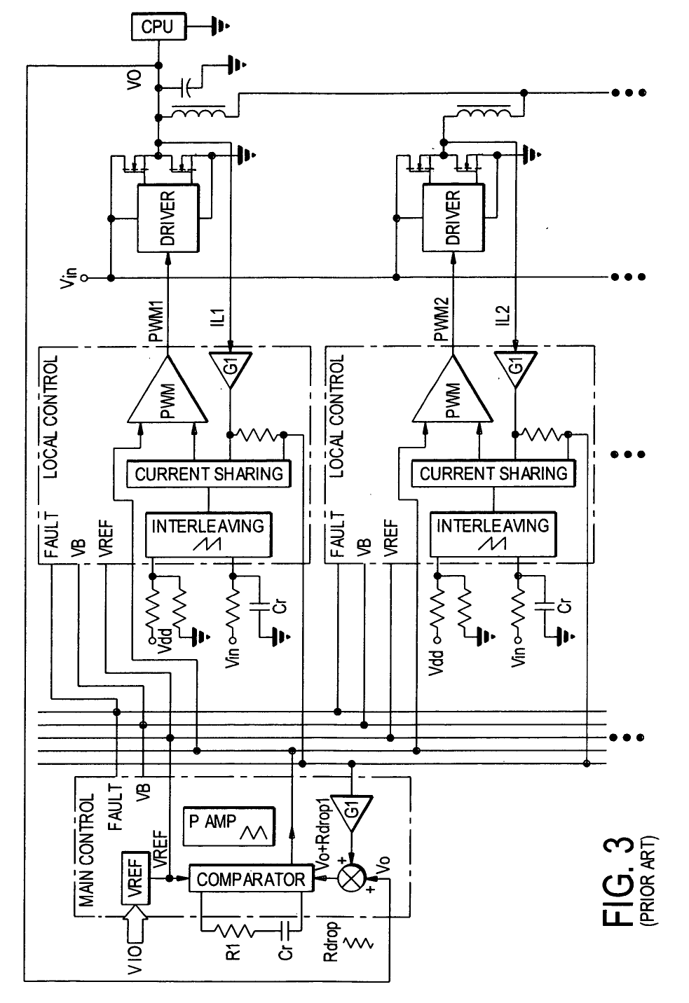

### DETAILED DESCRIPTION OF THE PREFERRED EMBODIMENTS

The present invention will be described with reference to the drawings. In the drawings, some like reference numbers indicate identical or functionally similar elements. Additionally, the left-most digit(s) of most reference numbers may identify the drawing in which the reference numbers first appear.

The invention will be explained in terms of exemplary embodiments. This specification discloses one or more embodiments that incorporate the features of this invention. The disclosure herein will provide examples of embodiments, including examples of data analysis from which those skilled in the art will appreciate various novel approaches and features developed by the inventors. These various novel approaches and features, as they may appear herein, may be used individually, or in combination with each other as desired.

In particular, the embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, persons skilled in the art may effect such feature, structure, or characteristic in connection with other embodiments whether or not explicitly described.

Embodiments of the invention may be implemented in hardware, firmware, software, or any combination thereof. Embodiments of the invention may also be implemented using instructions stored on a machine-readable medium, which may be read and executed by one or more processors.

In an exemplary embodiment, a power management system is provided that has increased power density and facilitates flexible phase design. FIG. 4 is a block schematic diagram illustrating an exemplary embodiment including a distributed control approach. In this example, power management circuit 400 comprises one or more phases 402, for example, six phases are shown. Each phase 402 comprises a control circuit 404 connected to a device and driver circuit 406. For example, control circuit 404 may be a feedback control circuit generating a pulse wave modulated signal to control the output of device and driver circuit 406. The outputs of the device and driver circuits 406 may be combined as output 408 and provided to a powered device, such as a CPU.

The controls in this embodiment, exemplified by control circuits 404, are preferably completely distributed into each individual channel. Each channel's current information feeds back only to the control associated with the channel. The output voltage feeds back to each channel's control. The communication between each channel's control is not through a master controller, but through bus lines or other simple wire connections. With help of these wire connections, the controller for each individual channel can work together to offer the function for the whole voltage regulator. Each channel's control can also work independently to control only a single channel.

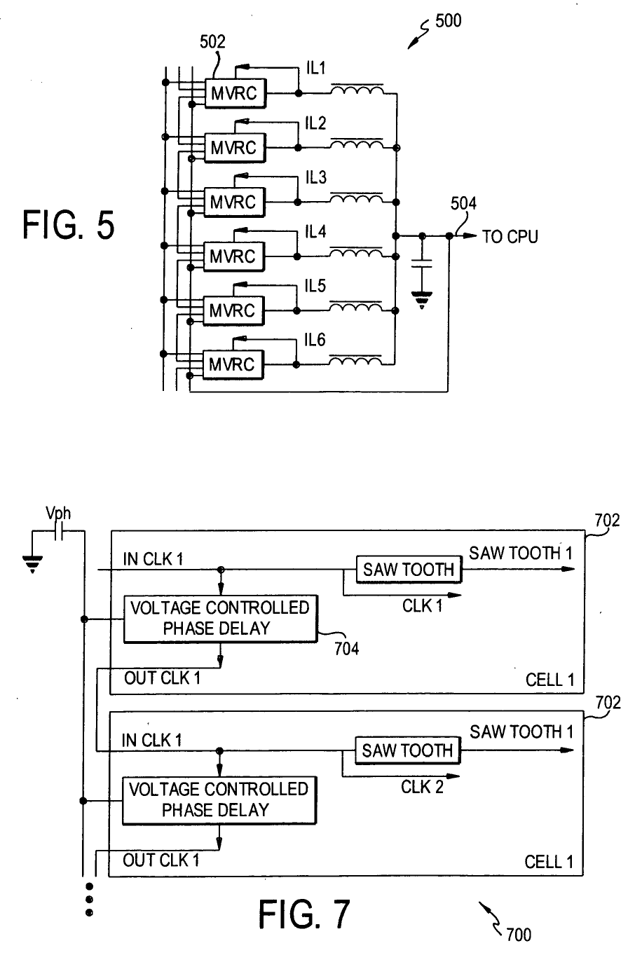

FIG. 5 is a block schematic diagram showing a circuit incorporating Monolithic/Modularized Voltage Regulator Channel (MVRC) circuits. Power management circuit 500 comprises one or more MVRC circuits 502. In an embodiment, MVRC circuit 502 is an integrated circuit comprising the elements of control circuit 404 and device and driver circuit 406 (shown in FIG. 4). MVRC circuits 502 each generate an output that may be combined as output 504 and provided to a powered device, such as a CPU.

In this embodiment, the distributed control circuits have been integrated into the power IC. This integration reduces chip counts and makes possible increased power density. An MVRC circuit 502 as shown herein can be used alone to support a regular POL load, or in a combination of multiple devices to support a CPU load as shown in FIG. 5.

The MVRC circuit 502 is preferably constructed with a fully distributed control scheme that achieves automatic current sharing, Adaptive Voltage Position (AVP), and automatic interleaving, all without channel number limitations. The inventors have developed novel methods of current sharing, AVP, and interleaving that are useful in this context and others. The current sharing, AVP and interleaving methods disclosed herein may therefore be applied in other contexts and the scope of the invention with regard to any of these methods is not limited to their use in the MVRC circuit, which is merely an example of an application for these concepts. Further, the inventors contemplate that any of the concepts disclosed herein may be used in combination with any number of the other concepts to provide a unique solution for a given application.

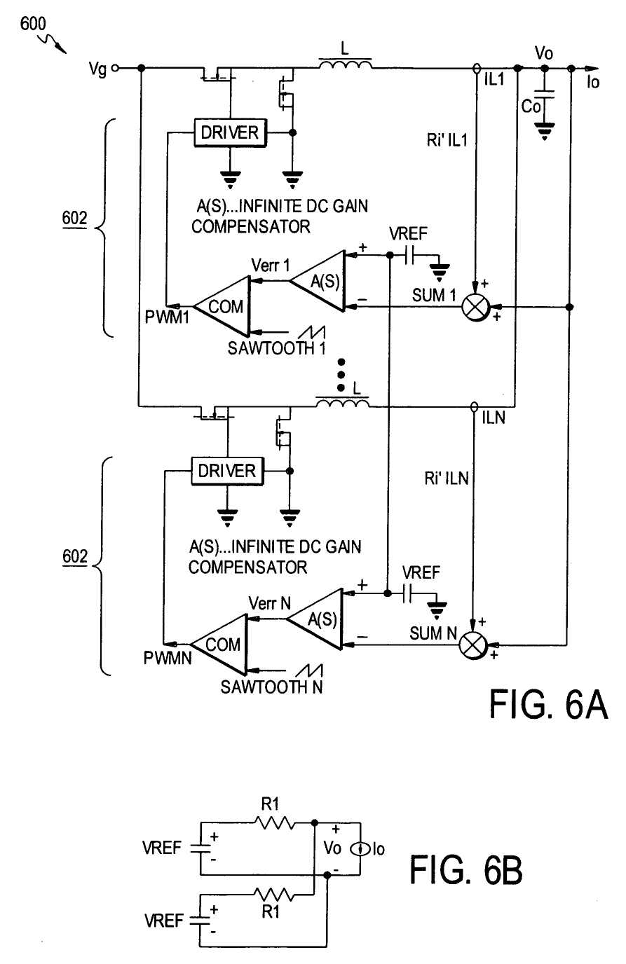

FIG. 6A is a block schematic diagram showing an exemplary embodiment of novel automatic current sharing and AVP circuits. The adaptive voltage position (AVP) provides a DC output voltage of the converter circuit that is dependent on the load. This approach increases the output voltage dynamic tolerance, reduces the number of capacitors required to regulate output voltage, and reduces the average power consumed by the CPU. To achieve AVP for a multi-channel converter, VR controllers have used sensed inductor current information to change voltage loop reference, but the current information processed is usually total inductor information. One benefit of this AVP approach is that only one compensator needed. That also means, however, that the control cannot be distributed. Dedicated circuitry is also needed for current sharing. In certain embodiments, the present AVP and current sharing scheme use another concept—“droop to each channel” (wherein a well-controlled system load line is constructed by building a well-controlled load line for each individual channel). There are many ways to realize a droop for each individual channel. FIG. 6A illustrates an exemplary implementation based on “active droop control”. Other possible implementations to build a well-controlled load line to each channel include “peak current control”, “current mode hysteretic control” and other methods that will be appreciated by those skilled in the art.

In an exemplary embodiment, as shown in FIG. 6A, a control circuit 600 implements active droop control to provide a well-controlled load line for one or more buck converters 602 serving one or more corresponding channels. In this embodiment, a separate active droop control is provided for each channel. Different channels may have large variation in their power stages, but may have the same equivalent circuit within the control bandwidth if Vref and Ri are designed to be the same. If all these channels share the same input and output, their equivalent circuits are connected in parallel and the resultant circuit can be easily determined. For example, if a VR is to have VID=1 v and RLL=1 mOhm, Vref will be designed to be 1 v, and each channel's current sensing gain should be N mOhm where N is the number of channels.

The equivalent circuit of each of these circuits can be simplified as a voltage source in series with a resistor as shown in FIG. 6B. The value of the voltage source is Vref, and the value of the resistor is Ri/N. In this way, a well-controlled VR load line can be achieved by building a well-controlled load line for each individual channel. As shown in the embodiment of FIG. 6A, the control is fully distributed and implements current sharing. If the load line of each channel is exactly the same, the current going through each channel is the same because their outputs are tied together. However, if there are tolerances between each channel's Vref and Ri, the current will be different. For the case of VR, the droop is flat. Therefore, the impact of Vref tolerance on current sharing is dominant. The current sharing becomes worse at light load and becomes better if the Vref tolerance is smaller. The impact of Vref tolerance on current sharing can be avoided if each channel's Vref is tied together. As a result, the current sharing will not change with load, which depends only on how well each channel's current sensing gain can be controlled.

Although each channel's Vref and current sensing gain can be well controlled, in reality these quantities have some variability. The load line of the whole system has a tolerance band (TOB) 608. The AVP TOB specifications for modem CPUs are very strict. Therefore, these tolerances must be analyzed during the design process to verify the ability of the circuit to meet CPU specifications. Tolerance analysis demonstrates that the embodiment shown has a better AVP tolerance band than conventional circuits.

As noted above, the embodiment of FIG. 6A provides a current sharing function. If the load line of each channel is exactly the same, the current passing through each should be the same because the outputs are tied together. However, if there are tolerances between each channel's Vref and Ri, the current will be different. And for the case of VR, the total AVP droop is just about 10% of the normal output voltage, and the impact of Vref tolerance is dominant. If each channel's Vref is tied together as shown, the impact of Vref tolerance can be completely bypassed. The current sharing will not change with load, but depends on how well each channel's current sensing gain is controlled.

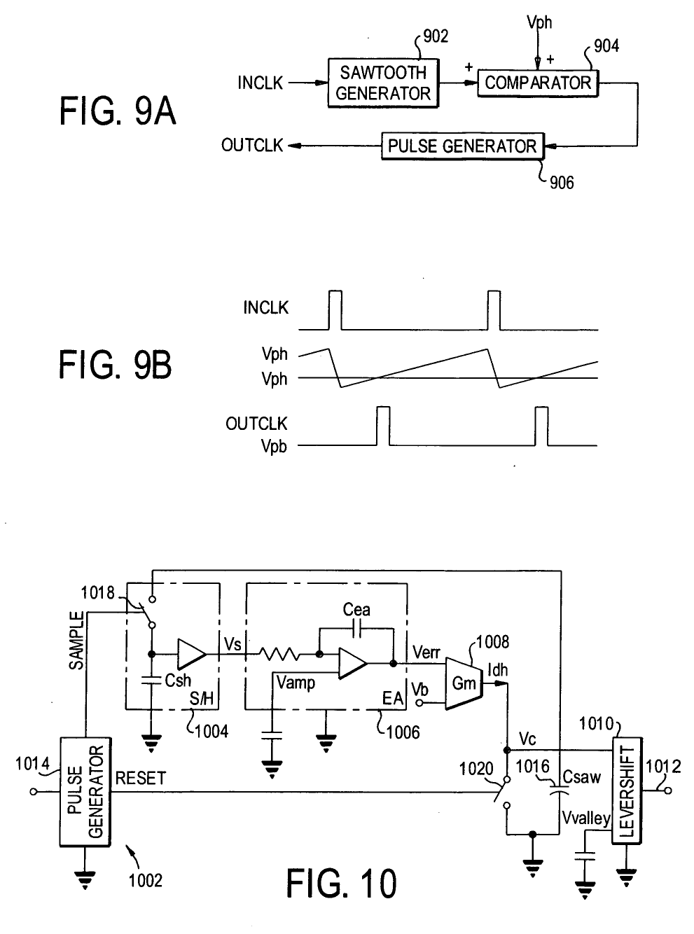

FIG. 7 shows a circuit for distributed interleaving according to an exemplary embodiment of the invention. In this example, circuit 700 comprises one or more cells 702. Each cell 702 comprises a voltage controlled phase delay 704. Each voltage controlled phase delay 704 has a clock signal as an input (InCLK) and a clock signal coming out (OutCLK) which is connected to the input of the next phase. InCLK is also connected within each cell to Sawtooth and a CLK output. An exemplary embodiment of the voltage controlled phase delay 704 between the InCLK and OutCLK signals is shown in more detail in FIG. 9A. A sawtooth generator 902 provides a sawtooth output to comparator 904 which has another input (Vph) and an output connected to a pulse generator 906. The output of pulse generator 906 is the OutCLK signal of the voltage controlled phase delay 704. As can be seen, the phase delay is controlled by Vph, which is set according to the phase number of the system. The phases do not obtain their phase position from another phase because the Inclk and OutCLK signals determine the relationship of each phase. If there are 3 phases, the Vph is set up to make the phase delay between the InCLK and OutCLK 120 degrees in each MVRC. If there are N phases, Vph is set up for a 360/N degree phase delay. Vph is changed as the number of phases is varied. The DC voltage Vph can be produced by an adjustable voltage reference like a model TL431 device, or can be the output of a Digital-to-Analog Converter (DAC). For microprocessor power management, this DAC can be integrated in the IC that supplies the VID power, therefore no external chips or other components are needed for interleaving. In an embodiment, in each MVRC chip, a saw-tooth generator produces a saw-tooth waveform to synch the InCLK signal. Thus, interleaving among each channel is achieved.

In preferred embodiments an accurate phase delay is generated according to Vph. It is possible to use a phase-locked loop to get the controlled phase delay. But a PLL cannot usually be monolithically integrated since the large outside capacitor is needed for the low pass filter within the PLL. In a preferred embodiment, rather than employing a PLL, a sawtooth generator and comparator are used to produce the delay. A leading edge saw-tooth may be produced to synch the InCLK signal. Vph compares with the leading-edge saw-tooth to get the timing, and after the pulse generator the OutCLK signal is obtained which will be used as the InCLK signal for the next phase.

FIGS. 8A and 8B are waveform diagrams that illustrate the timing relationship between InCLK1 and InCLK2. As can be seen in the diagrams, the sawtooth waveforms Sawtooth1 and Sawtooth2 generate clock signals that are accurately offset. FIG. 9B illustrates the waveforms found in the circuit of FIG. 9A.

To obtain an accurate phase delay, the saw-tooth waveform must be accurate, and to achieve carrier matching between channels, an accurate saw-tooth generator that is both layout and process insensitive is desirable. In an embodiment, a self-adjusted saw-tooth generator is provided to meet these goals.

FIG. 10 is a schematic diagram showing an exemplary embodiment of a self-adjusted saw-tooth generator. In this embodiment, sawtooth generator circuit 1000 comprises pulse generator 1002, sampling circuit 1004, error amplifier 1006, transconductance amplifier 1008, and level shift circuit 1010.

In operation, a sawtooth waveform is provided at output 1012, synchronized with the incoming CLK signal at clock input 1014. The slope, amplitude, valley and peak values of the saw-tooth waveform are automatically self-adjusted to the specified value, independent of circuit layout and process. Thus, no trimming is needed for circuit 1000. Circuit 1000 can be monolithically integrated without any external components using typical digital CMOS processes.

Circuit 1000 uses a changeable current Ich instead a fixed current to charge capacitor 1016 Csaw to produce a saw-tooth waveform Vc. Vc is level-shifted by level shifter 1012 (if necessary) to produced final output voltage Vsaw at output 1012.

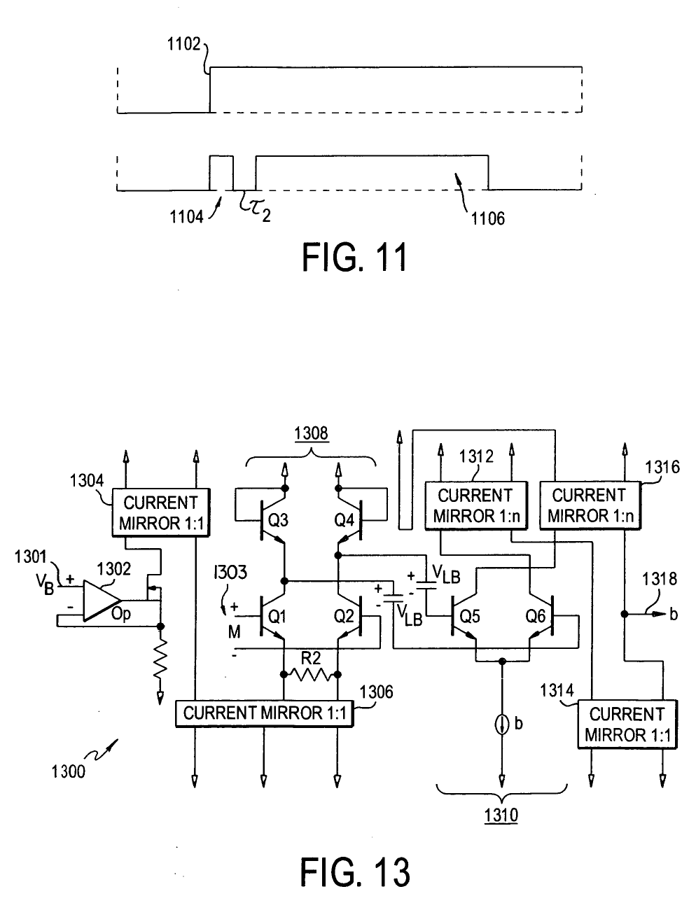

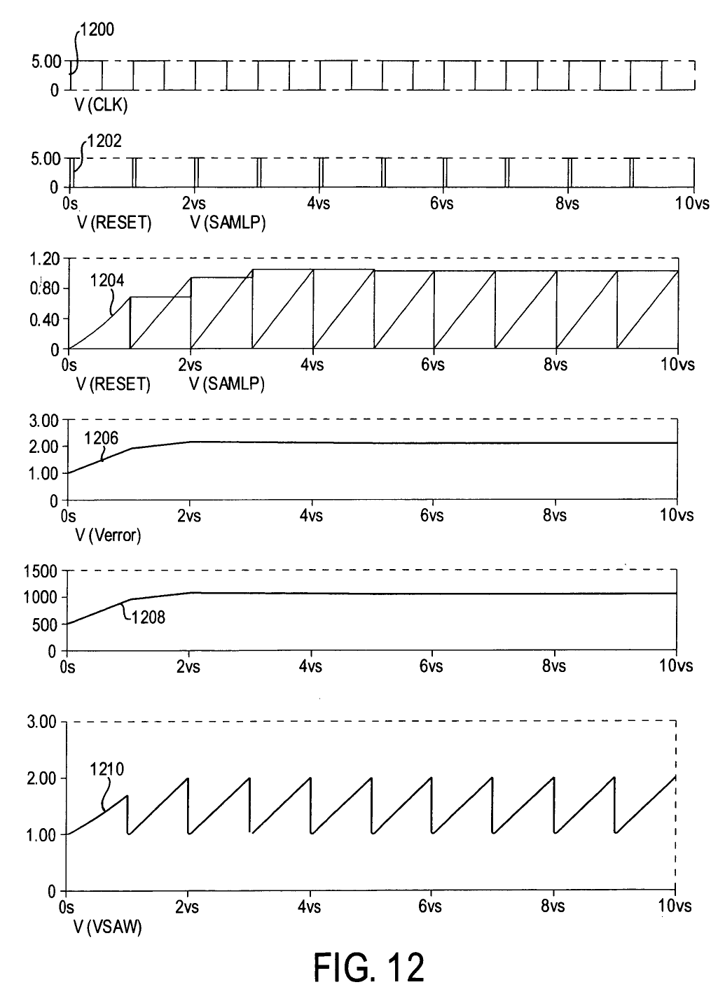

FIGS. 11 and 12 show simulated waveforms that further explain the operation of circuit 1000. The CLK signal at input 1014 in the circuit of FIG. 10 defines the switching frequency and has a period T. Referring now to FIG. 11, a pulse generator produces two narrow pulses synchronizing the incoming CLK signal 1102. As shown in FIG. 11, sample pulse 1104 is triggered by the rising edge of the CLK signal 1102 and has a pulse width Υ1. Reset pulse 1106 is triggered by the falling edge of the sample pulse 1104 but with a tiny delay τ2 to guarantee there is no overlap between the sample pulse 1104 and the reset pulse 1106 that has a pulse width τ3.

Referring now to FIG. 12, a series of sample pulses 1104 (shown in waveform 1202) control sample and hold circuit 1004 using switch 1018 (both shown in FIG. 10) to catch the value of Vc when sample=“1”. Reset pulse 1106 (also shown in waveform 1202) controls a switch 1020 (shown in FIG. 10) to reset the voltage across Csaw when reset=“1”. The sampled Vc value, designated Vs (shown at 1204), and a voltage reference Vamp are fed into error amplifier 1006 to produce an error voltage Verr, shown in waveform 1206. This Verr is then transferred to a current Ich (shown at 1208) by transconductance amplifier 1008. Csaw is charged by Ich and reset by switch 1020 to produce a saw-tooth signal Vc across Csaw. Since the Error amplifier 1006 is basically an integrator that has an infinite DC gain, the amplitude of Vc will be settled down to the value defined by Vamp after several switching cycles if the feedback loop is stable to produce Vsaw (shown at 1210). Vc can be level-shifted using level shifter 1010 to be on top of Vvalley using an op amp circuit if the designed valley of the output saw tooth is not GND. In FIG. 12, Vsaw is shown with a valley of +1 v.

For the final output saw-tooth signal Vsaw (1210), the frequency is synchronized with CLK (1200); the amplitude is defined by Vamp; the valley value is defined by Vvalley; the peak valley is defined by Vvalley+Vamp; the slope is defined by Vamp/(T-τ3). Vamp and Vvalley can come from a bandgap reference. T is the same for each channel, which is guaranteed by the connection shown in FIG. 6a and is usually set by an external resistor. Therefore, Vsaw can be produced by setting voltage Vamp and Vvalley. The accuracy of the slope, amplitude, valley and peak values, and the matching of different saw-tooth waveforms produced by different silicon chips can be guaranteed by the schematic design and made insensitive to layout and process variations. The self-adjusting process does not affect the system because the PWM or other control actions of the system can be active only after the saw-tooth is settled down to the designed value, which only takes a few switching CLK periods.

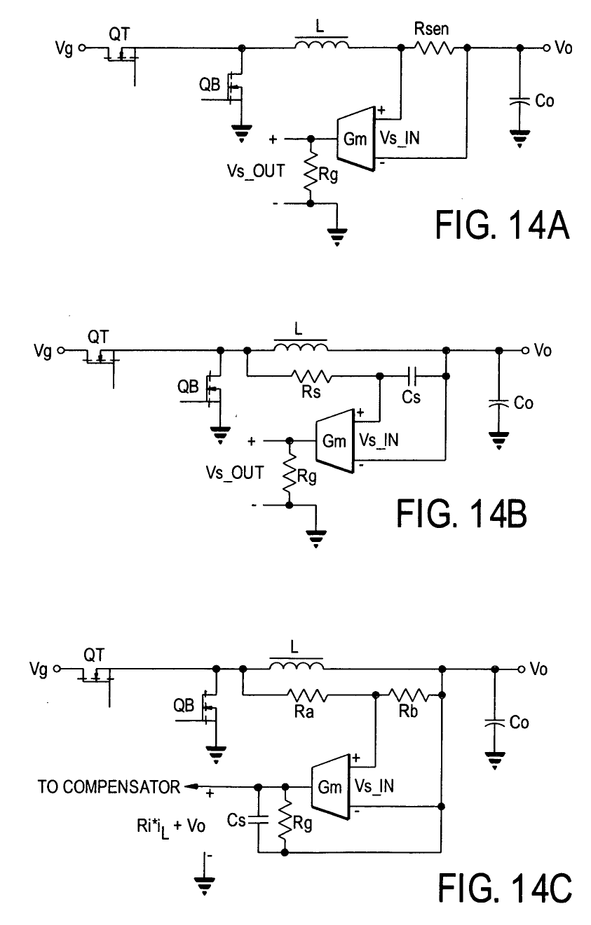

FIG. 13 is a schematic diagram of an improved transconductance amplifier circuit 1300 that can be used in the circuits of FIGS. 14A through 14C.

Circuit 1300 comprises simple op amp 1302, current mirrors 1304 and 1306, first stage 1308, gain cell 1310, and current mirrors 1312, 1314 and 1316. Input 1301 provides a bandgap reference voltage V_{B}. Input 1303 is converted to an output current Io at output 1318.

In operation, circuit 1300 op amp 1302 receives the bandgap reference voltage at input 1301 and creates from the reference voltage a current that is passed through cascading current mirrors 1304 and 1306 to become the bias current of first stage 1308. Gain cell 1310 is provided with a controlled reference current, such as an oscillator setting current, as its bias current, shown at I_{B}. Resistors R1 and R2 are matched to provide an accurate operating ratio without absolute value trimming. A cascading current mirror comprising, for example, current mirrors 1312, 1314 and 1316 is designed to have a large dynamic range to provide accurate amplification of the output current from the first stage 1308 and gain cell 1310.

In FIG. 6A, the current information iL1˜-iL2 may come from a traditional current sensing circuit. Preferably, this information is provided by a novel current sensing circuit, examples of which are shown in FIGS. 14A, 14B and 14C. FIG. 14A is a schematic diagram of a current sensing circuit using external resistor Rsen as a sensing element. In this scheme, the current sensing gain Ri=Rsen·Gm·Rg. FIG. 14B is a schematic diagram of an exemplary current sensing circuit using inductor DCR R_{L} as a sensing element. If the circuits are designed so that Rs*Cs=L/R_{L}, the waveform of Vs_in will follow the inductor current waveform, and the current sensing gain is Ri=RL·Gm·Rg. The benefits of the current sensing circuits shown in FIGS. 14A and 14B include simple integrated circuit implementation. FIG. 14C is the schematic diagram of another exemplary current sensing circuit using inductor DCR R_{L} as a sensing element. If the circuit is designed so that Rs*Cs=L/R_{L}, the waveform of voltage across Cs will following the inductor current waveform, and the current sensing gain is Ri=R_{L}·Gm·Rg·(Rb/(Ra+Rb)). The benefits of the current sensing circuit shown in FIG. 14C compared to the circuit FIG. 14B include that the signal provided to the Gm amplifier is a large signal rather than a small signal. A signal “Vo+Ri*iL” (which is desirable for AVP implementation) can also be achieved without an adder by connecting the Rg and Cs from the output of the transconductance amplifier (Gm) to the Vo (instead from the output of Gm to Gnd). As shown in FIG. 14C, the voltage at the output node of Gm is equal to “Vo+Ri*iL”. For the current sensing scheme in FIG. 14A and FIG. 14B, the signal “Vo+Ri*iL” can also be achieved by connecting resistor Rg from the output of the transconductance amplifier (Gm) to the Vo (instead from the output of Gm to Gnd). In the embodiments of FIGS. 14A through 14C, the transconductance amplifier Gm is a useful and valuable component to achieve accurate current sensing gain.

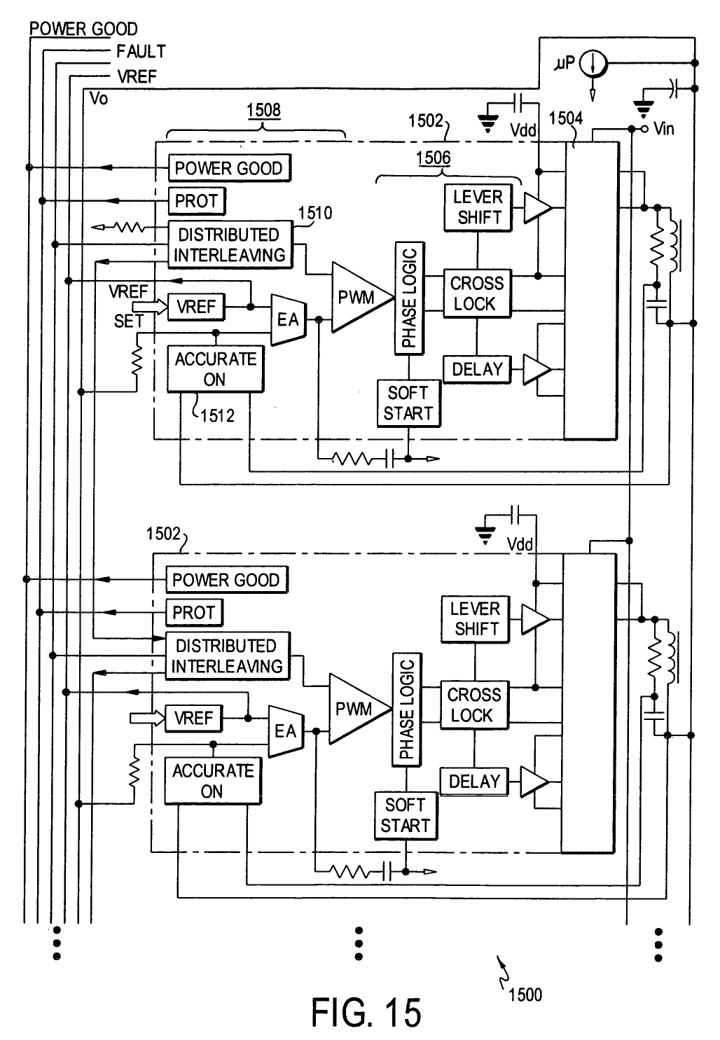

In an embodiment, an integrated circuit may be provided embodying one or more of the features described herein. As noted above, these integrated circuits can be used in parallel to provide power in phase, or can be used individually. Referring to FIG. 15, a circuit incorporating a plurality of these integrated circuit devices 1502 is shown at 1500. In the embodiment shown, each device 1502 has a power MOSFET 1504, driver circuits 1506, and control circuits 1508 integrated in a single die. Preferably, device 1502 comprises distributed interleaving integrated circuit 1510, which may be, for example, an implementation of the circuit of FIG. 6A. Device 1502 may also comprise accurate transconductance amplifier circuit 1512, which may be, for example, an implementation of the circuit of FIG. 14A or FIG. 14B.

In the exemplary embodiment shown, each chip receives only its own channel's current information. This eliminates the need for long current feedback lines in circuit 1500. The output voltage is provided as feedback to each device 1502. In this exemplary embodiment only two bus lines are required, both providing DC levels that are insensitive to noise. One bus line is a voltage reference from a DAC of one of the devices 1502, and the other is the voltage setup for automatic interleaving which is also derived from the DAC of a device 1502. There are CLK lines connecting the devices 1502. If an overall circuit design is changed so that another channel is required, another device 1502 can be added and connected with the Phase delay bus and Vref bus in the same way as the other devices. Thus, as many channels as desired can be configured. The devices 1502 can be standardized, such as by fixing the I/O type and number; droop can be programmed by sensing gain, and the DAC can be configured to provide different Vref voltages. In this way, the device 1502 can be used as a generic power IC for regular POL loads and for constructing CPU power supplies.

The present invention has been described above with the aid of functional building blocks and method steps illustrating the performance of specified functions and relationships thereof. The boundaries of these functional building blocks and method steps have been arbitrarily defined herein for the convenience of the description. Alternate boundaries can be defined so long as the specified functions and relationships thereof are appropriately performed. Any such alternate boundaries are thus within the scope and spirit of the claimed invention. One skilled in the art will recognize that these functional building blocks can be implemented by discrete components, application specific integrated circuits, processors executing appropriate software and the like or any combination thereof. Thus, the breadth and scope of the present invention should not be limited by any of the above-described exemplary embodiments, but should be defined only in accordance with the claims and their equivalents.

While various embodiments of the present invention have been described above, it should be understood that they have been presented by way of example only, and not limitation. Thus, the breadth and scope of the present invention should not be limited by any of the above-described exemplary embodiments, but should be defined only in accordance with the following claims and their equivalents.

We claim:

1. A power supply device, comprising:
at least one single integrated circuit including a power transistor circuit, a driver circuit connected to drive the power transistor circuit, and a distributed control circuit connected to the driver and power transistor circuits and controlling the operations of the driver and power transistor circuits;
wherein the distributed control circuit included in the single integrated circuit operates the device without an external controller in response to at least one clocking signal to provide a synchronized power output.

2. The device of claim 1, wherein the synchronized power output of the integrated circuit is a continuous power output.

3. The device of claim 1, wherein the synchronized power output of the integrated circuit is a periodic output during a defined portion of a duty cycle.

4. The device of claim 3, wherein the device comprises a plurality of said single integrated circuits connected in parallel and wherein the synchronized power outputs of each of the integrated circuits are combined to provide a continuous power output.

5. The device of claim 3, wherein each integrated device further comprises an interleaving circuit that processes an input timing signal, selectively activates the device, and provides an output timing signal to the interleaving circuit of another integrated device.

6. The device of claim 5, wherein a phase delay of the interleaving circuit is set by a reference voltage.

7. The device of claim 6, wherein the reference voltage is varied depending on the number of integrated devices included in the circuit.

8. The device of claim 5, further comprising a sawtooth wave generator connected to the interleaving circuit to provide the input timing signal.

9. The current sensing scheme comprises a transconductance amplifier.

10. The device of claim 9, wherein the transconductance amplifier comprises a first stage, a gain cell, and a cascaded current mirror connected in series.

11. The device of claim 4, wherein each integrated device is connected to share current at the synchronized power outputs.

12. The device of claim 6, wherein the control circuit of each integrated device comprises an active droop control circuit.

13. A method of providing power to a processor, comprising:
providing a plurality of single integrated circuits, each including a power transistor circuit, a driver circuit connected to drive the power transistor circuit, and a distributed control circuit connected to the driver and power transistor circuits and controlling the operations of the driver and power transistor circuits;
operating the integrated circuits so that each integrated circuit provides a power output during a phase dependent on its connection to the other circuits, with the phase timing determined in response to a timing signal received from another of the single integrated circuits; and
combining the power outputs of each of the integrated circuits to provide a continuous power output.

14. The method of claim 13, wherein each integrated device further comprises an interleaving circuit, wherein one or more of the integrated devices performs the further steps of:
processing an input timing signal,
selectively activating a power output, and
providing an output timing signal to the interleaving circuit of another integrated device.

15. The method of claim 14, including the further step of setting a phase delay of the interleaving circuit using a reference voltage.

16. The method of claim 15, including the further step of varying the reference voltage depending on the number of integrated devices included in the circuit.

17. The method of claim 14, comprising the further step of using a sawtooth wave generator connected to the interleaving circuit to provide the input timing signal.

18. The method of claim 17, comprising the further step of providing a transconductance amplifier in the sawtooth wave generator.

19. The method of claim 18, wherein the step of providing a transconductance amplifier comprises providing a circuit including a first stage, a gain cell, and a cascaded current mirror connected in series.

20. The method of claim 13, comprising the further step of connecting each integrated device to share current at their power outputs.

21. The method of claim 13, further comprising the step of operating the control circuit using an active droop control circuit.
